(19) United States
(12) Patent Application Publication
(10) Pub. No.: US 2003/0080335 A1
(43) Pub. Date: May 1, 2003

(54) Semiconductor device, and verification method for semiconductor testing apparatus and method using the semiconductor device

(75) Inventor: Toshiaki Koyama, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/134,385

(22) Filed: Apr. 30, 2002

(30) Foreign Application Priority Data
Oct. 29, 2001 (JP) P2001-330522

(51) Int. Cl. H01L 23/58

(52) U.S. Cl. 257/48

(57) ABSTRACT

The present invention provides a verification method capable of verifying a semiconductor testing apparatus and/or method with reliability, and also provides a semiconductor device for use in the verification. Spare elements in predetermined locations in a spare region of the semiconductor device are intentionally provided with defects and whether the semiconductor testing apparatus and/or method can detect those defects with reliability is checked for verification of the semiconductor testing apparatus and/or method. First and second spare regions (2, 4) are provided as spare regions for a memory array (8), with defects being intentionally produced in memory cells in predetermined locations in the second spare region (4). Switching between memory cells in the memory array (8) and those in the first and second spare regions (2, 4) is done by a control circuit (9). Which ones of the memory cells are to be switched is indicated to the control circuit (9) by blowing desired fuses in LT fuse groups (1, 3) corresponding respectively to the first and second spare regions (2, 4).

### BACKGROUND OF THE INVENTION

1. Field of the Invention

The present invention relates to a semiconductor device such as a semiconductor memory in which a large number of elements are formed and also to a method of verifying a semiconductor testing apparatus and method for testing the operation of the semiconductor device.

2. Description of the Background Art

In a semiconductor device such as a memory or a logic LSI, there are formed vast numbers of elements (including transistors and capacitors). And, the number of built-in elements is increasing as new semiconductor devices are developed.

Such numerous elements in the semiconductor device are not always manufactured as intended and defects are likely to occur in some elements due to the influence of various factors in the manufacturing process.

For this reason, whether a semiconductor device which has gone through the manufacturing process functions as intended is tested using a semiconductor testing apparatus such as an LSI tester and/or a semiconductor testing method such as providing the semiconductor device with a test pattern.

In general, memories and logic LSIs have a spare element region formed on the same substrate in case of defects occurring in internal elements in a finished product. Then, switching is performed in such a way that circuits which were connected to defective elements are connected to spare elements in the spare region, thereby achieving improvement in product yield.

FIG. 6 shows a semiconductor device provided with such a spare region. In this example, a memory is taken as an illustration of the semiconductor device. As shown in FIG. 6, this semiconductor device comprises a memory array 8 where a plurality of memory cells which are elements are formed, and a spare region 2 where spare memory cells each corresponding to one of the memory cells are formed.

Switching from the memory cells in the memory array 8 to those in the spare region 2 is done by a control circuit 9. Which ones of the memory cells in the memory array 8 are to be switched is indicated to the control circuit 9 by blowing desired fuses in an LT (Laser Trimming) fuse group 1 which is connected through wires 10 to the control circuit 9. Here, the LT fuses in the LT fuse group 1 refer to fuses which are blown by laser radiation, and the blowing of the LT fuses causes switching of circuits in the control circuit 9.

In the case where a program such as a test program or timing analysis program is executed by the semiconductor testing apparatus and/or method to test whether manufactured semiconductor devices work as intended, if the semiconductor testing apparatus and/or method itself for carrying out the testing has faults, defects, if any, in finished semiconductor devices cannot be detected.

Thus, a need exists for verification of the semiconductor testing apparatus and/or method itself. A verification method conventionally employed is, for example, a technique for intentionally changing the contents of expected values to be obtained and then modifying a program in the semiconductor testing apparatus and/or method to check the expected values against resultant values obtained by the operation of the semiconductor device, thereby checking whether the semiconductor testing apparatus and/or method can detect such false defects with reliability.

However, such a conventional verification method may not ensure reliable testing in some cases. For example, even if a semiconductor memory is tested using a semiconductor testing apparatus for testing memory cells in the whole area on chip, it is possible that actual testing is performed only on memory cells in some areas on chip because of faults in the operating program of the testing apparatus. In that case, defects, if any, in areas beyond the range testable by the semiconductor testing apparatus will be overlooked.

In the conventional verification method, it is impossible to verify whether the semiconductor testing apparatus and/or method as in the above example can really test memory cells in the whole area on chip. This is because the conventional verification method only modifies data within the range testable by the semiconductor testing apparatus and/or method. Therefore, it is difficult for the conventional verification method to clearly determine whether or not the semiconductor testing apparatus and/or method can detect defects in a prototype semiconductor device with reliability.

### SUMMARY OF THE INVENTION

An object of the present invention is to provide a verification method capable of verifying a semiconductor testing apparatus and/or method with reliability. The present invention also provides a semiconductor device for use in the verification.

According to a first aspect of the present invention, the semiconductor device includes: an element region; a spare region; a control circuit; and element-to-be-switched indicator. In the element region, a plurality of elements are formed. In the spare region, spare elements corresponding to some or all of the plurality of elements are formed. The control circuit switches any ones or all of the plurality of elements into the spare elements. The element-to-be-switched indicator indicates to the control element which of the plurality of elements is to be switched into a corresponding one of the spare elements in accordance with an externally given instruction. A defect is intentionally produced in a spare element in a predetermined location in the spare region.

Intentionally producing a defect in a spare element in a predetermined location in the spare region allows the production of a semiconductor device whose defective parts are previously known by indicating to the element-to-be-switched indicator to switch any desired element in the element region into a defective element in the spare region. And, the produced semiconductor device can be used for verification of the semiconductor testing apparatus and/or method.

Preferably, in the semiconductor device, the element-to-be-switched indicator includes a plurality of fuses for switching circuits in the control circuit by being blown.

In this semiconductor device, by blowing the fuses, any desired element in the element region can be easily switched into a defective element in the spare region.

Preferably, in the semiconductor device, the element-to-be-switched indicator includes a plurality of switches for switching circuits in the control circuit upon receipt of control signals.

In this semiconductor device, by applying the control signals to the plurality of switches, any desired element in the element region can be easily switched into a defective element in the spare region.

Preferably, the semiconductor device further includes: storage for receiving and storing the control signals from outside and outputting the control signals to the element-to-be-switched indicator.

In this semiconductor device, outputting the control signals from the storage eliminates the necessity for continuously applying the control signals to the plurality of switches from outside.

According to a second aspect of the present invention, a method of verifying a semiconductor testing apparatus and/or method using any one of the semiconductor device includes the following steps (a) to (c). The step (a) is to indicate to the element-to-be-switched indicating means to switch an element in a predetermined location in the element region into the spare element intentionally provided with the defect. The step (b) is to test the semiconductor device using the semiconductor testing apparatus and/or method. The step (c) is to verify whether, in the testing, the semiconductor testing apparatus and/or method outputs a verification result that the element in the predetermined location in the element region is defective.

In this method, it is verified whether, in the testing, the semiconductor testing apparatus and/or method outputs a result that the element in a predetermined location in the element region is defective. That is, if the semiconductor testing apparatus and/or method outputs the result that the element in the predetermined location is defective, they can be judged as functioning properly. If not, they can be judged as not functioning properly. This permits reliable verification of the semiconductor testing apparatus and/or method.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a semiconductor device according to a first preferred embodiment;

FIG. 2 is a flow chart showing a method of verifying a semiconductor testing apparatus and/or method using the semiconductor device according to the first preferred embodiment;

FIG. 3 shows a semiconductor device according to a second preferred embodiment;

FIG. 4 shows a semiconductor device according to a third preferred embodiment;

FIG. 5 shows a semiconductor device according to a fourth preferred embodiment; and

FIG. 6 shows a conventional semiconductor device.

### DESCRIPTION OF THE PREFERRED EMBODIMENTS

<First Preferred Embodiment>

This preferred embodiment provides a semiconductor device, and a verification method for verifying a semiconductor testing apparatus and/or method by intentionally producing defects in spare elements in predetermined locations in a spare region of the semiconductor device and then checking whether the semiconductor testing apparatus and/or method can detect the defects with reliability.

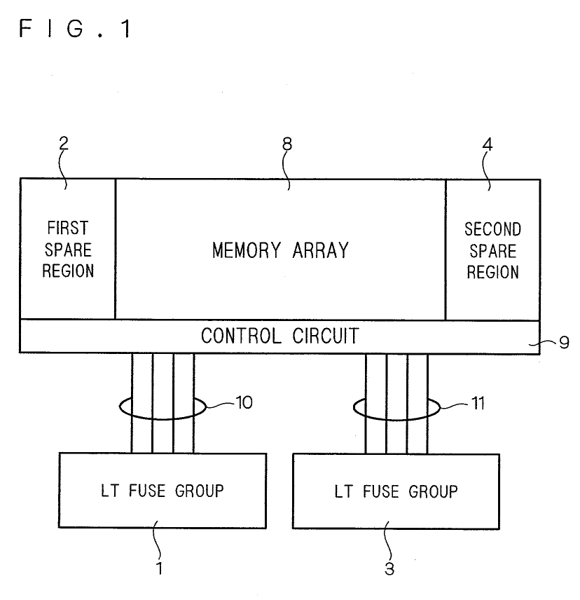

FIG. 1 shows a semiconductor device according to this preferred embodiment. In this example, a memory is taken as an illustration of the semiconductor device. As shown in FIG. 1, this semiconductor device comprises a memory array 8 where a plurality of memory cells which are elements are formed, and a first spare region 2 where spare memory cells each corresponding to one of the memory cells are formed.

The semiconductor device further comprises a second spare region 4 identical in configuration to the first spare region 2. In the second spare region 4, however, spare elements in predetermined locations (any given locations determined by the operator who verifies the semiconductor testing apparatus and/or method) are intentionally provided with defects. Those defects are produced by breaking or destroying the memory cells. The spare memory cells in the first spare region 2 are formed without any defects.

Switching between the memory cells in the memory array 8 and those in the first spare region 2 or the second spare region 4 is done by a control circuit 9. More specifically, switching between the memory cells in the memory array 8 and those in the first spare region 2 is indicated to the control circuit 9 by blowing desired fuses in an LT fuse group 1 which is connected through wires 10 to the control circuit 9. Similarly, switching between the memory cells in the memory array 8 and those in the second spare region 4 is indicated to the control circuit 9 by blowing desired fuses in an LT fuse group 3 which is connected through wires 11 to the control circuit 9.

If, in this way, spare elements in predetermined locations in the spare region of the semiconductor device are intentionally provided with defects, it becomes possible to produce a semiconductor device whose defective parts are previously known by indicating to the LT fuse group 3, which is element-to-be-switched indicating means, to switch predetermined elements in the memory array 8, which is an element region, into defective elements in the spare region. And, the produced semiconductor device can be used for verification of a semiconductor testing apparatus and/or method.

Further, the semiconductor device comprises, as the element-to-be-switched indicating means, the LT fuse group 3 for switching circuits in the control circuit 9 by being blown; therefore, switching of any desired elements in the memory array 8 to defective elements in the second spare region 4 can be done easily by blowing the fuses.

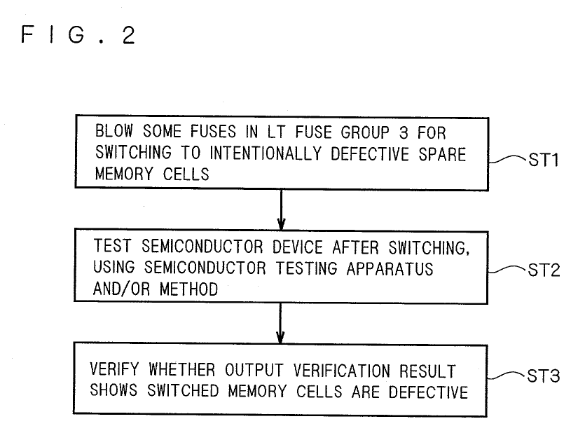

Now, the method of verifying the semiconductor testing apparatus and/or method using the semiconductor device of FIG. 1 will be described with reference to FIG. 2. First, in step ST1 of FIG. 2, some fuses in the LT fuse group 3 are blown so that desired memory cells in the memory array 8 are switched into spare memory cells having intentional defects. Then in step ST2, the semiconductor device after switching is tested using the semiconductor testing apparatus and/or method.

In step ST3, it is verified whether or not the semiconductor testing apparatus and/or method outputs a verification result that the switched memory cells are defective.

According to this verification method, if the semiconductor testing apparatus and/or method outputs the result that the switched memory cells are defective, the apparatus and/or method can be judged as functioning properly. If not, the apparatus and/or device can be judged as not functioning properly. This permits reliable verification of the semiconductor testing apparatus and/or method.

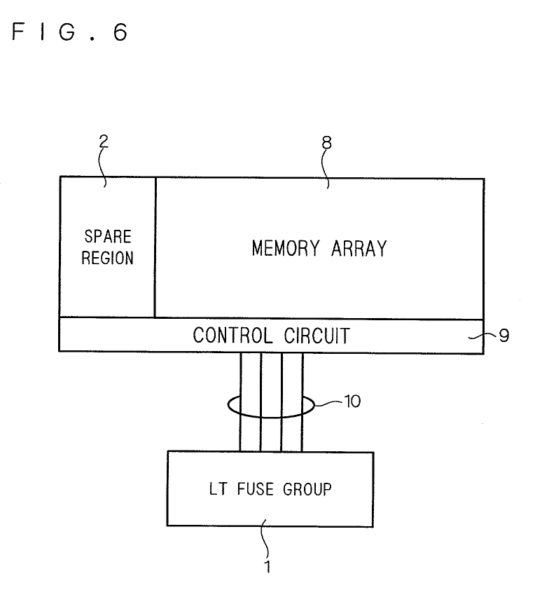

In this preferred embodiment, the spare region is divided into the proper first spare region 2 and the second spare region 3 having intentional defects. The spare region, however, does not have to be divided into two in this way. For example in the case of the semiconductor device of FIG. 6, defects may be intentionally produced in some elements in the spare region and the LT fuses corresponding to those defective elements may be blown. Even in that case, the same verification as above described can be conducted.

While in this preferred embodiment a memory is taken as an illustration of the semiconductor device, other components such as a logic LSI may be employed and configured as above described. That is, defective parts should be intentionally produced in the spare region of a logic LSI and switching to the defective parts should be performed for verification of a testing apparatus and/or method.

<Second Preferred Embodiment>

This preferred embodiment provides a modification of the semiconductor device according to the first preferred embodiment. More specifically, this preferred embodiment uses electric fuses instead of the LT fuses.

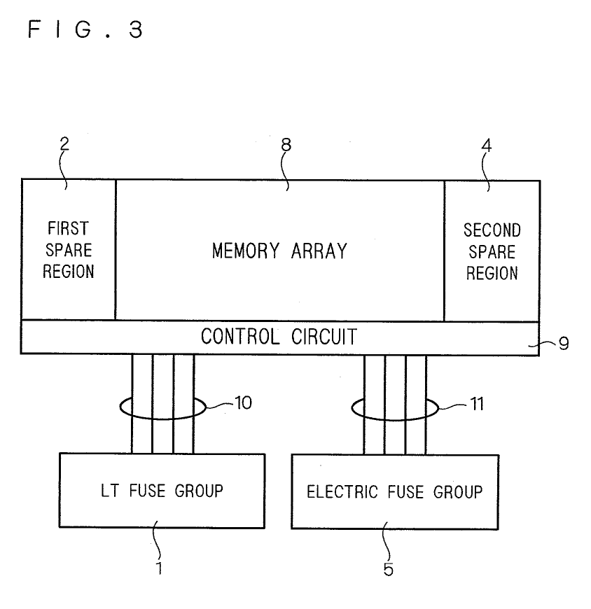

FIG. 3 shows a semiconductor device according to this preferred embodiment. As shown in FIG. 3, this semiconductor device comprises an electric fuse group 5 instead of the LT fuse group 3. In this example, electric fuses in the electric fuse group 5 refer to fuses which are blown by large current flow of a predetermined value or more, and the blowing of these electric fuses causes switching of circuits in the control circuit 9.

The other parts of the configuration are identical to those of the semiconductor device according to the first preferred embodiment and therefore, the description thereof will be omitted.

Even where the electric fuse group 5 replaces the LT fuse groups 1 and 3, the spare region, as in the first preferred embodiment, does not necessarily have to be divided into two parts: the proper first spare region 2 and the second spare region 4 having intentional defects.

Further, the verification method using the semiconductor device according to this preferred embodiment is, except that it uses the electric fuses instead of the LT fuses, identical to the verification method according to the first preferred embodiment.

<Third Preferred Embodiment>

This preferred embodiment provides another modification of the semiconductor device according to the first preferred embodiment. More specifically, this preferred embodiment uses transistors instead of the LT fuses.

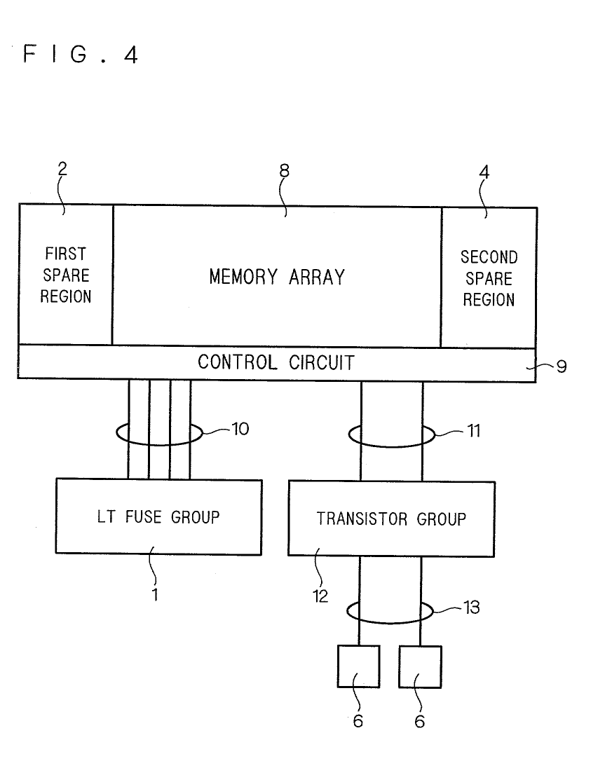

FIG. 4 shows a semiconductor device according to this preferred embodiment. As shown in FIG. 4, this semiconductor device comprises a transistor group 12 instead of the LT fuse group 3. In this example, transistors in the transistor group 12 refer to switches which function as alternatives to fuses for switching paths from on to off and vice versa upon receipt of control signals at their control electrodes (e.g., gate electrodes for MOSFETs: Metal Oxide Semiconductor Field Effect Transistors). This transistor control enables switching of circuits in the control circuit 9. Control of the transistor group 12 is achieved by the application of control signals to external pads 6 each of which is connected through wires 13 to each of the control electrodes in the transistor group 12.

In this fashion, the semiconductor comprises, as the element-to-be-switched indicating means, the transistor group 12 for switching circuits in the control circuit 9 upon receipt of the control signals; therefore, switching of any desired elements in the element region to defective element in the spare regions can be done easily.

The other parts of the configuration are identical to those of the semiconductor device according to the first preferred embodiment and therefore, the description thereof will be omitted.

Even where the transistor group 12 replaces the LT fuse groups 1 and 3, the spare region, as in the first preferred embodiment, does not necessarily have to be divided into two parts: the proper first spare region 2 and the second spare region 4 having intentional defects.

Further, the verification method using the semiconductor device according to this preferred embodiment is, except that it uses the transistors instead of the LT fuses, identical to the verification method according to the first preferred embodiment.

<Fourth Preferred Embodiment>

This preferred embodiment provides a modification of the semiconductor device of the third preferred embodiment. More specifically, in this preferred embodiment, the control signals applied to the transistor group 12 are given not directly from the external pads 6 but once stored in a register before application.

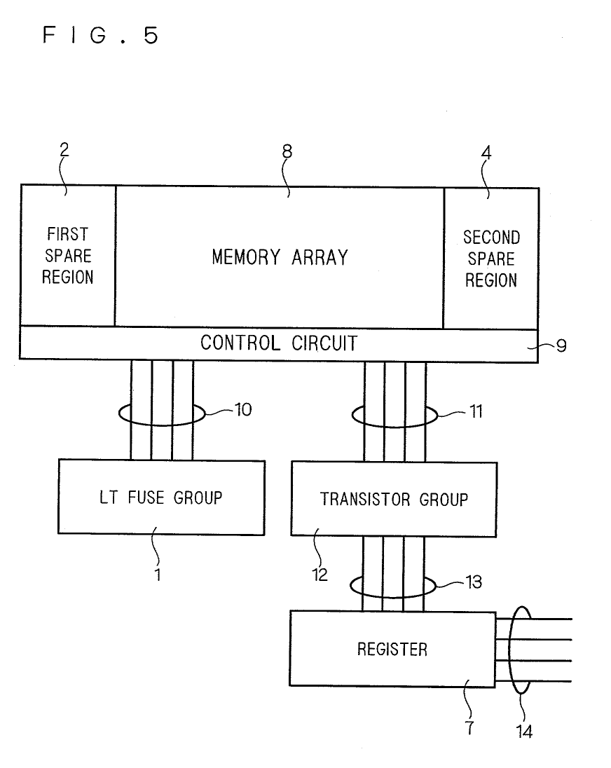

FIG. 5 shows a semiconductor device according to this preferred embodiment. As shown in FIG. 5, a register 7 is connected through the wires 13 to the transistor group 12. The register 7 receives control signals from outside through wires 14 and stores therein the contents of the signals.

The register 7 applies the stored control signals to the transistor group 12. The transistor group 12 switches paths from on to off and vice versa according to the control signals, thereby indicating to the control circuit 9 which ones of the memory cells in the memory array 8 are to be switched. In this fashion, the presence of the register 7 avoids the necessity for continuously applying control signals from outside to the transistor group 12.

The other parts of the configuration are identical to those of the semiconductor device according to the third preferred embodiment and therefore, the description thereof will be omitted.

Further, the verification method using the semiconductor device according to this preferred embodiment is, except for the addition of the register 7, identical to the verification method according to the third preferred embodiment.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an element region in which a plurality of elements are formed;
a spare region in which spare elements corresponding to some or all of said plurality of elements are formed;
a control circuit for switching any ones or all of said plurality of elements into said spare elements; and
element-to-be-switched indicating means for indicating to said control element which of said plurality of elements is to be switched into a corresponding one of said spare elements in accordance with an externally given instruction,
wherein a defect is intentionally produced in a spare element in a predetermined location in said spare region.

2. The semiconductor device according to claim 1, wherein
said element-to-be-switched indicating means includes a plurality of fuses for switching circuits in said control circuit by being blown.

3. The semiconductor device according to claim 2, wherein
said fuses are blown by laser radiation.

4. The semiconductor device according to claim 2, wherein
said fuses are blown by current flow of a predetermined value or more.

5. The semiconductor device according to claim 1, wherein
said element-to-be-switched indicating means includes a plurality of switches for switching circuits in said control circuit upon receipt of control signals.

6. The semiconductor device according to claim 5, further comprising:
storage means for receiving and storing said control signals from outside and outputting said control signals to said element-to-be-switched indicating means.

7. The semiconductor device according to claim 5, wherein
said plurality of switches are transistors.

8. The semiconductor device according to claim 1, wherein
said element region is a memory area.

9. The semiconductor device according to claim 1, further comprising:
in addition to said spare region including said spare element provided with said defect,
another spare region in which spare elements corresponding to some or all of said plurality of elements are formed without any defects.

10. A method of verifying a semiconductor testing apparatus and/or method using the semiconductor device according to claim 1, comprising the steps of:
(a) indicating to said element-to-be-switched indicating means to switch an element in a predetermined location in said element region into said spare element intentionally provided with said defect;
(b) testing said semiconductor device using said semiconductor testing apparatus and/or method; and
(c) verifying whether, in said testing, said semiconductor testing apparatus and/or method outputs a verification result that said element in said predetermined location in said element region is defective.
